(19) United States
(12) Patent Application Publication
(10) Pub. No.: US 2026/0204872 A1
(43) Pub. Date: Jul. 16, 2026

(54) LASER DIODE AND OPTICAL INTEGRATED CIRCUIT INCLUDING THE SAME

(71) Applicant: SAMSUNG ELECTRONICS CO., LTD., Suwon-si (KR)

(72) Inventors: Jaesoong LEE, Suwon-si (KR); Younggeun ROH, Suwon-si (KR); Dongsik SHIM, Suwon-si (KR)

(73) Assignee: SAMSUNG ELECTRONICS CO., LTD., Suwon-si (KR)

(21) Appl. No.: 19/439,739

(22) Filed: Jan. 5, 2026

(30) Foreign Application Priority Data
Jan. 15, 2025 (KR) 10-2025-0006386

(51) Int. Cl. H01S 5/12; G01S 7/481

(52) U.S. Cl. CPC H01S 5/12; G01S 7/4814

(57) ABSTRACT

A laser diode may include a substrate, a first semiconductor layer, an active layer, and a second semiconductor layer, which are sequentially stacked on the substrate in a vertical direction of the laser diode, and a plurality of pattern layers spaced apart from each other in a horizontal direction of the laser diode, on the second semiconductor layer, wherein widths of the plurality of pattern layers are different from each other in the horizontal direction.

### CROSS-REFERENCE TO RELATED APPLICATION

This application claims the benefit of Korean Patent Application No. 10-2025-0006386, filed on January 15, 2025, in the Korean Intellectual Property Office, the disclosure of which is incorporated herein in its entirety by reference.

### BACKGROUND

### 1.Field

One or more embodiments of the present disclosure relate to a laser diode and an optical integrated circuit including the same.

### 2.Description of the Related Art

Heterojunction laser diodes may be formed by transferring group III-group V epitaxial layers onto a silicon substrate. The heterojunction laser diodes frequently undergo mode hopping due to thermal expansion or hole burning. Mode hopping may refer to a sudden and unpredictable change in a lasing wavelength (mode) of a laser diode. When mode hopping occurs, the laser may fail to maintain a stable output at a single wavelength (i.e., a single mode) and instead jumps between multiple modes (i.e., multiple modes), leading to performance instability. To prevent this problem while ensuring stable single-mode operation, exponential modulation or gain modulation methods are employed. However, these methods require highly sophisticated techniques and have a low success rate because processes must be performed near a gain material.

### SUMMARY

One or more embodiments provide a laser diode with improved mode hopping phenomenon. Additional aspects will be set forth in part in the description which follows and, in part, will be apparent from the description, or may be learned by practice of the presented embodiments.

According to an aspect of the disclosure, a laser diode includes a substrate, a first semiconductor layer, an active layer, and a second semiconductor layer, which are sequentially stacked on the substrate in a vertical direction of the laser diode, and a plurality of pattern layers spaced apart from each other in a horizontal direction of the laser diode, on the second semiconductor layer, wherein widths of the plurality of pattern layers may be different from each other in the horizontal direction.

According to one or more embodiments, the plurality of pattern layers are spaced apart from each other at non-periodic intervals.

According to one or more embodiments, the widths of the plurality of pattern layers may gradually increase along the horizontal direction.

According to one or more embodiments, the plurality of pattern layers may be spaced apart from each other at non-periodic intervals that range from 10 nm to 100 nm.

According to one or more embodiments, the widths of the plurality of pattern layers may range from 150 nm to 1000 nm.

According to one or more embodiments, the plurality of pattern layers may each include silicon oxide.

According to one or more embodiments, a portion of an area of the second semiconductor layer, in which the plurality of pattern layers are not provided, may be doped.

According to one or more embodiments, the laser diode may further include a first contact provided on the plurality of pattern layers.

According to one or more embodiments, the laser diode may further include a second contact provided on the substrate.

According to one or more embodiments, the first semiconductor layer may be an n-type semiconductor layer and the second semiconductor layer may be a p-type semiconductor layer.

According to one or more embodiments, the laser diode may include a distributed feedback (DFB) Laser.

According to another aspect of the disclosure, an optical integrated circuit includes a light source, an optical element configured to transmit light from the light source, and a photodetector configured to convert light received through an optical waveguide into an electrical signal, wherein the light source may include a substrate, a first semiconductor layer, an active layer, and a second semiconductor layer, which are sequentially stacked on the substrate in a vertical direction of the light source, and a plurality of pattern layers spaced apart from each other on the second semiconductor layer in a horizontal direction of the light source, wherein widths of the plurality of pattern layers may be different from each other in the horizontal direction.

According to one or more embodiments, the optical integrated circuit may further include an optical modulator disposed on the optical element.

According to one or more embodiments, the optical integrated circuit may further include an electronic circuit configured to apply modulation signals to the optical modulator.

According to one or more embodiments, the plurality of pattern layers are spaced apart from each other at non-periodic intervals.

According to one or more embodiments, a portion of an area of the second semiconductor layer, in which the plurality of pattern layers are not provided, may be doped.

According to another aspect of the disclosure, a light detection and ranging (LiDAR) device includes a light transmitter configured to radiate light onto a target object, a light receiver configured to receive the light reflected from the target object, a processor configured to obtain position information about the target object based on light received from the light receiver, and an optical element configured to provide a path for the light to travel within the light transmitter or the light receiver, wherein the light transmitter includes a light source, the light source includes a substrate, a first semiconductor layer, an active layer, and a second semiconductor layer, which are sequentially stacked on the substrate in a vertical direction of the light source, and a plurality of pattern layers spaced apart from each other in a horizontal direction of the light source on the second semiconductor layer, wherein widths of the plurality of pattern layers are different from each other in the horizontal direction.

According to one or more embodiments, the light transmitter may be further configured to steer the light output from the light source toward the target object.

According to one or more embodiments, the plurality of pattern layers are spaced apart from each other at non-periodic intervals.

According to one or more embodiments, a portion of an area of the second semiconductor layer, in which the plurality of pattern layers are not provided, may be doped.

### BRIEF DESCRIPTION OF THE DRAWINGS

These and/or other aspects will become apparent and more readily appreciated from the following description of the embodiments, taken in conjunction with the accompanying drawings in which:

FIG. 1 is a perspective view illustrating a laser diode according to one or more embodiments;

FIG. 2 shows graphs representing an intensity and gain of a laser diode according to one or more embodiments;

FIG. 3 shows graphs representing an intensity and gain of a laser diode according to one or more embodiments;

FIGS. 4 to 6 show graphs representing an intensity and hole density of a laser diode according to one or more embodiments;

FIG. 7 shows graphs representing an intensity and hole density of a laser diode according to one or more embodiments;

FIG. 8 is a schematic diagram illustrating a LiDAR device according to one or more embodiments;

FIG. 9 is a block diagram showing a schematic configuration of an electronic device including a LiDAR device according to one or more embodiments;

FIGS. 10 and 11 are conceptual diagrams, where FIG. 10 is a side view and FIG. 11 is a plan view, illustrating the application of the LiDAR device according to the embodiment in a vehicle; and

FIG. 12 is a block diagram conceptually showing an example configuration of an optical integrated circuit according to one or more embodiments.

### DETAILED DESCRIPTION

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items.

Hereinafter, with reference to the attached drawings, a laser diode and an optical integrated circuit including the same according to various embodiments are described in detail. In the drawings below, the same reference numerals denote the same components, and the size of each component in the drawings may be exaggerated for clarity and ease of explanation. In addition, the embodiments described below are merely examples, and various modifications are possible from these embodiments.

Hereinafter, the terms “upper” and “on” may include not only things that are directly above and in contact, but also things that are above in a non-contact manner. Singular expressions shall include plural expressions unless the context clearly indicates otherwise. Additionally, when a part is said to “comprise” a component, this does not mean that it excludes other components, but rather that it may include other components, unless otherwise specifically stated.

The definite article “the” and similar referential terms may denote both singular and plural forms. Unless the steps of a method are explicitly described in a particular order or in a different order, these steps may be performed in any suitable order and are not necessarily limited to the order described.

The connections or lack of connections of lines between components shown in the drawings are example representations of functional connections and/or physical or circuit connections, which may be represented by various alternative or additional functional, physical, or circuit connections in the actual device.

Any use of examples or example terms is merely intended to elaborate technical ideas and is not intended to limit the scope of the disclosure unless otherwise defined by the claims.

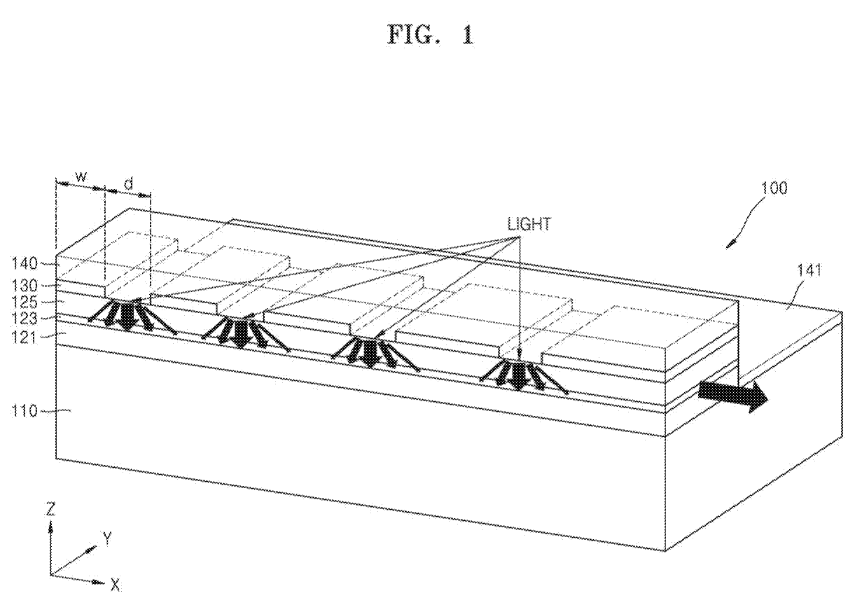

FIG. 1 is a perspective view illustrating a laser diode 100 according to one or more embodiments.

Referring to FIG. 1, the laser diode 100 may include a substrate 110, a first semiconductor layer 121, an active layer 123, and a second semiconductor layer 125, which are sequentially stacked on the substrate 110 in a vertical direction (e.g., a z-axis direction), and a plurality of pattern layers 130 spaced apart from each other in a horizontal direction (e.g., an x-axis direction) on the second semiconductor layer 125.

The substrate 110 may include a semiconductor material. The substrate 110 may include, for example, silicon (Si), germanium (Ge), silicon germanium (SiGe), silicon carbide (SiC), gallium arsenide (GaAs), indium arsenide (InAs), indium phosphide (InP), or the like. The substrate 110 may be a silicon on insulator (SOI) substrate. The substrate 110 may include an insulating material, such as an oxide, silicon nitride, silicon oxynitride, or the like.

The laser diode 100 may include a structure in which the first semiconductor layer 121 of a first conductivity type, the active layer 123, and the second semiconductor layer 125 of a second conductivity type are sequentially stacked on the substrate 110.

The first semiconductor layer 121 is doped with the first conductivity type, and the second semiconductor layer 125 may be doped with the second conductivity type that is electrically opposite to the first conductivity type. For example, the first semiconductor layer 121 may be doped with an n-type dopant while the second semiconductor layer 125 is doped with a p-type dopant, or the first semiconductor layer 121 may be doped with a p-type dopant while the second semiconductor layer 125 is doped with an n-type dopant. One of the first semiconductor layer 121 and the second semiconductor layer 125 may be a III-V compound semiconductor layer doped with the n-type dopant, and the other may be a III-V compound semiconductor layer doped with the p-type dopant.

The active layer 123 generates light through recombination of electrons and holes injected from the first semiconductor layer 121 and the second semiconductor layer 125. For this purpose, the active layer 123 may have a quantum well structure in which a quantum well is disposed between barriers. A wavelength of light generated in the active layer 123 may be determined by an energy bandgap of a material forming the quantum well in the active layer 123. The active layer 123 may include a single quantum well or a multi-quantum well (MQW) structure including multiple quantum wells. An energy level of the quantum well in the conduction band may be chosen to be lower than that of the barrier. For this purpose, the barrier and the quantum well within the active layer 123 may include different compound semiconductors or compound semiconductors with different compositions.

The first semiconductor layer 121, the active layer 123, and the second semiconductor layer 125 may include, for example, a III-V compound semiconductor based on gallium nitride (GaN). For example, the first semiconductor layer 121, the active layer 123, and the second semiconductor layer 125 may include III-V compound semiconductors such as GaN, indium gallium nitrid (InGaN), aluminum indium gallium nitride (AlInGaN), aluminum gallium indium phosphide (AlGaInP), or the like, and the first semiconductor layer 121 and the second semiconductor layer 125 may be doped in opposite types to each other. The first semiconductor layer 121, the active layer 123, and the second semiconductor layer 125 may include, for example, III-V compound semiconductors based on GaAs.

For example, the first semiconductor layer 121 and the second semiconductor layer 125 may contain GaN and may be doped in opposite conductivity types to each other. That is, the first semiconductor layer 121 may include a GaN layer doped with an n-type dopant, and the second semiconductor layer 125 may include a GaN layer doped with a p-type dopant. In another embodiment, the first semiconductor layer 121 may include a p-type GaN layer, and the second semiconductor layer 125 may include an n-type GaN layer. The active layer 123 may include, for example, InGaN, and a composition ratio of In to Ga may be adjusted depending on a desired emission wavelength.

For example, the active layer 123 may have a stacked structure in which the first barrier, the quantum well, and the second barrier are sequentially stacked. The first barrier may be, for example, a GaN barrier, which may be doped with Si or may remain undoped. The quantum well may have the single quantum well structure or the multi-quantum well structure. For example, the quantum well may include a single-stacked structure or a multi-stacked structure of InGaN/GaN or InGaN/GaN/AlGaN. The composition ratio of In to Ga in the InₓGa₁₋ₓN stacked structure forming the quantum well may be adjusted depending on the emission wavelength. The GaN in the stacked structure forming the quantum well may be doped with Si or may remain undoped.

A plurality of pattern layers 130 may be provided on the second semiconductor layer 125. The plurality of pattern layers 130 may include silicon oxide. The plurality of pattern layers 130 may include, for example, silicon oxide (SiO₂).

The plurality of pattern layers 130 may have different widths w from one another. The widths w of the plurality of pattern layers 130 may progressively increase or decrease along a first direction (x-axis direction). In some embodiments, the widths may follow a specific trend, such as, a monotonic increase in width from one pattern layer to the next, a monotonic decrease, an increasing-then-decreasing pattern, or a decreasing-then-increasing pattern. Specifically, the widths w of the plurality of pattern layers 130 may gradually increase and then decrease along the first direction (x-axis direction). The widths w of the plurality of pattern layers 130 may gradually decrease along the first direction (x-axis direction). The widths of the plurality of pattern layers 130 may gradually decrease and then increase along the first direction (x-axis direction). The different widths w may be configured to create an aperiodic spatial distribution that influences current injection or optical properties. The widths w of the plurality of pattern layers 130 may be, for example, about 10 nm to about 1,000 nm. The widths w of the plurality of pattern layers 130 may be, for example, about 150 nm to about 1,000 nm.

Spacings d between the plurality of pattern layers 130 may be different from one another along the x-axis direction. The spacings d between the plurality of pattern layers 130 may be non-uniform or aperiodic, rather than following a regular interval. The spacings d between the plurality of pattern layers 130 may be, for example, about 10 nm to about 100 nm.

A portion of an area of the second semiconductor layer 125, in which the plurality of pattern layers 130 are not provided, may be doped. Holes may be injected through an ion implantation process between the plurality of pattern layers 130.

The laser diode 100 may further include a first contact 140 provided on the plurality of pattern layers 130 and a second contact 141 provided on the substrate 110. The first contact 140 may be formed using, for example, platinum (Pt), palladium (Pd), aluminum (Al), gold (Au), and nickel (Ni), either alone or in combination. The second contact 141 may be formed using, for example, Pt, Pd, Al, Au, and Ni, either alone or in combination.

The laser diode 100 may include a distributed feedback laser including a periodic structure (grating) to achieve single-mode lasing.

The laser diode according to the embodiment, by including the plurality of pattern layers on the second semiconductor layer, may modulate gain without affecting the active layer, and mode hopping may be prevented.

In one or more embodiments of the present disclosure, a light source such as a laser diode is configured by applying aperiodic current injection to a gain material. This approach suppresses gain in undesired modes while enabling operation in a selected target mode. After transferring a III-V semiconductor layer onto a silicon-on-insulator (SOI) wafer, aperiodic patterning of an insulating material (e.g., SiO₂) may be performed, forming SiO₂ patterns (e.g., the plurality of pattern layers 130) prior to the top metal contact process. This method simplifies the fabrication process and enhances efficiency, while also effectively stabilizing the single-mode operation of the light source. The spacing between the SiO₂ patterns may be gradually increased, facilitating relatively smooth hole injection in the region corresponding to the target mode. In contrast, adjacent modes experience regions with reduced or no current injection, thereby inhibiting stimulated emission in those undesired modes.

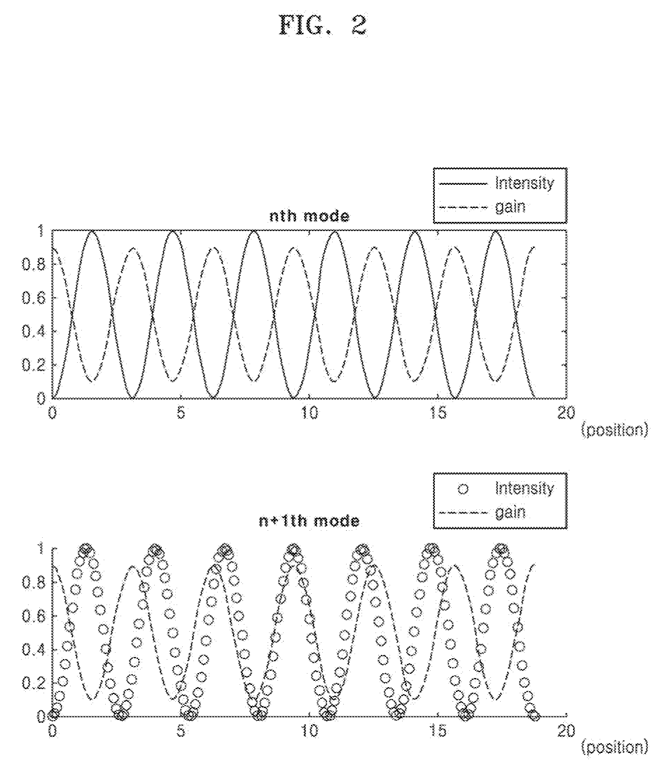

FIG. 2 shows graphs representing an intensity and gain of a laser diode according to one or more embodiments. The x-axis of the graphs represent the horizontal positions of the laser diode 100 with a patterned structure, while the y-axis represents normalized values of intensity and gain.

In laser diodes, a standing wave interference pattern may be formed, the period of which may be half the wavelength of incident light. In a medium region where constructive interference occurs, a shortage of holes may occur, which is called hole burning. This causes the laser diode to switch from one resonant optical mode to another. Here, a mode refers to a specific longitudinal resonant frequency (or wavelength) that is supported by the laser diode. The transition from the current resonant mode (an nth mode) to a neighboring mode (an (n+1)th mode) is known as mode hopping. The mode hopping induces instability in a laser output wavelength, disrupting precise wavelength control.

Referring to FIG. 2, by adjusting the widths of the plurality of pattern layers (130 in FIG. 1) provided on the second semiconductor layer (125 in FIG. 1), an overlap between the gain and the nth mode may be maximized, and an overlap between the gain and the n+1th mode may be minimized by controlling the position where the holes are injected. For example, when the spacing between the plurality of pattern layers (130 in FIG. 1) is reduced, hole feeding to the n+1th mode may decrease, thereby delaying oscillation as much as possible. This may prevent the mode hopping from the nth mode to the n+1th mode.

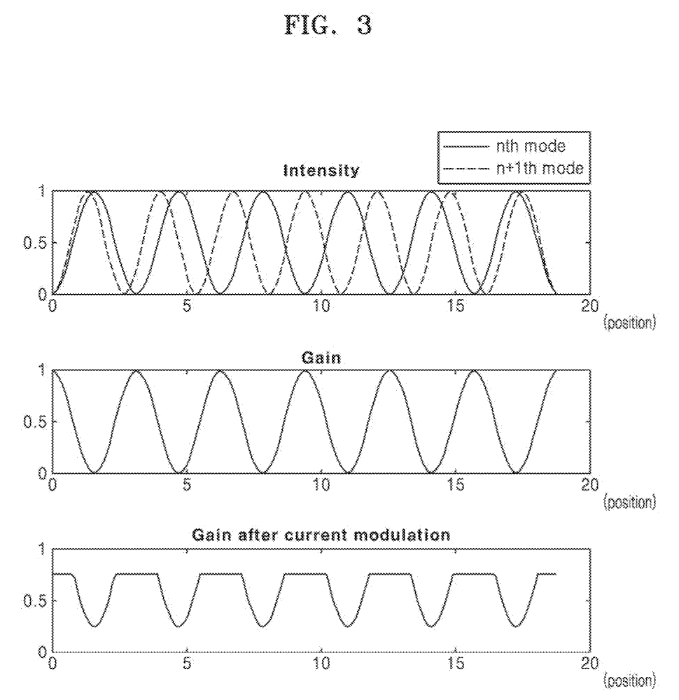

FIG. 3 shows graphs representing an intensity and gain of a laser diode according to one or more embodiments. The x-axis of the graphs represent the horizontal positions of the laser diode 100 with a patterned structure, while the y-axis represents normalized values of intensity or gain.

Referring to FIG. 3, it may be verified that the gain may be adjusted through current modulation under the same total current condition. By supplying more holes to the nth mode or reducing the holes supplied to the n+1th mode, the survivability of the nth mode may be enhanced, an oscillation of an n±1th mode may be delayed, and thus the mode hopping from the nth mode to the n+1th mode may be suppressed.

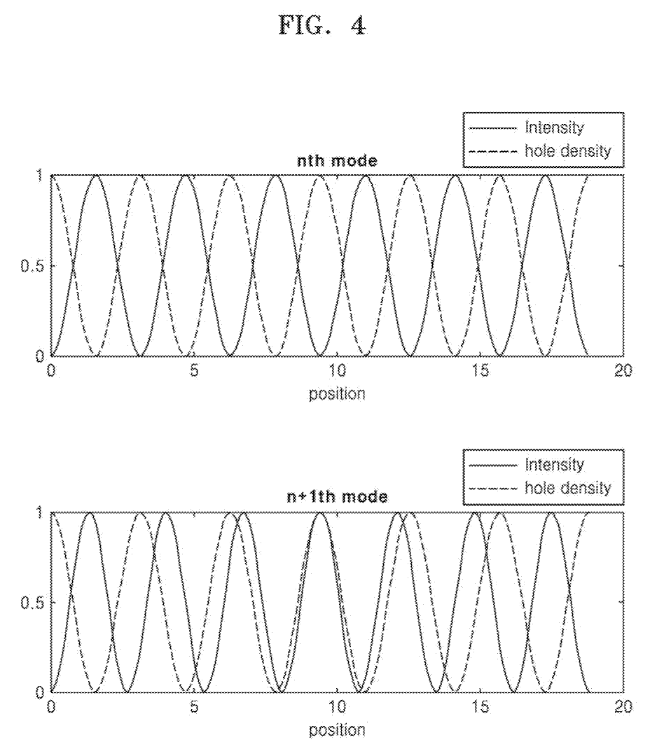

FIGS. 4 to 6 show graphs representing an intensity and hole density of a laser diode according to one or more embodiments.

Referring to FIG. 4, the mode hopping from the nth mode to the n+1th mode may occur. Under the same total current condition, the hole density may be maintained equally in the nth mode and the n+1th mode. At the point where the intensity of the nth mode has a maximum, the hole density has a value of 0, whereas the intensity and hole density of the n+1th mode overlap in some region, so the mode hopping from the nth mode to the n+1th mode may occur.

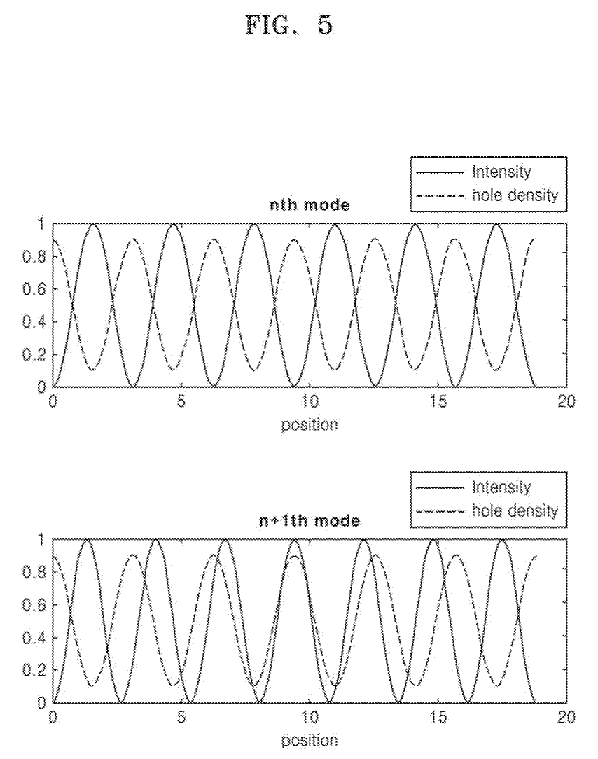

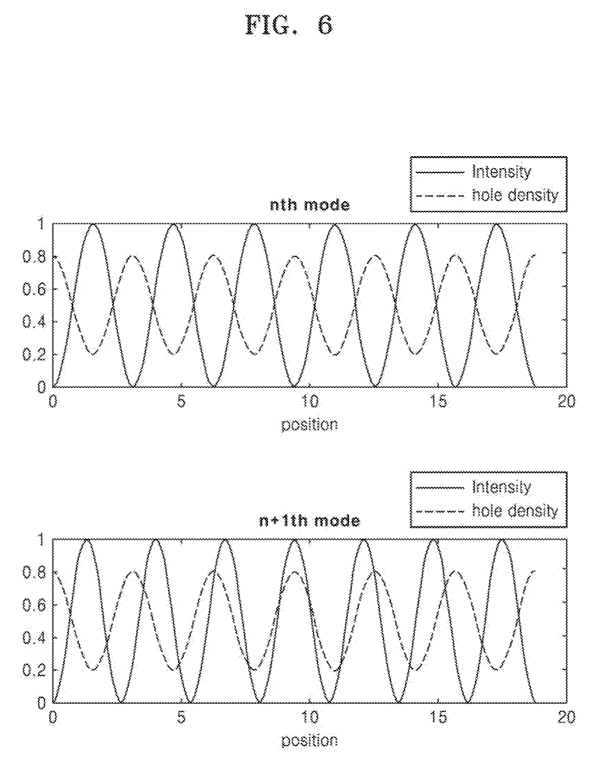

Referring to FIGS. 5 and 6, it may be verified that, under the same total current condition, the hole density remains the same in the nth mode and the n+1th mode, while the maximum value of the hole density decreases and the minimum value increases. This increases hole supply to nth mode, and the mode hopping from the nth mode to the n+1th mode may be suppressed.

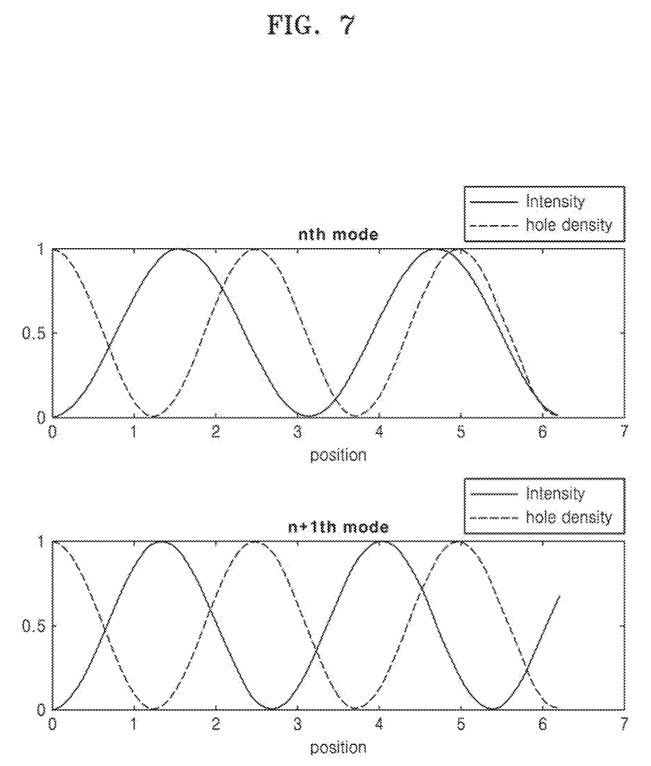

FIG. 7 shows graphs representing an intensity and hole density of a laser diode according to one or more embodiments.

Referring to FIG. 7, when hole injection is aperiodically modulated at n=1000, 1/3-area integral values of the nth mode and the n+1th mode may be verified. This indicates that when the hole injection is aperiodically modulated, the overlap of the nth mode increases while the overlap of the n+1th mode decreases, thereby maintaining the nth mode.

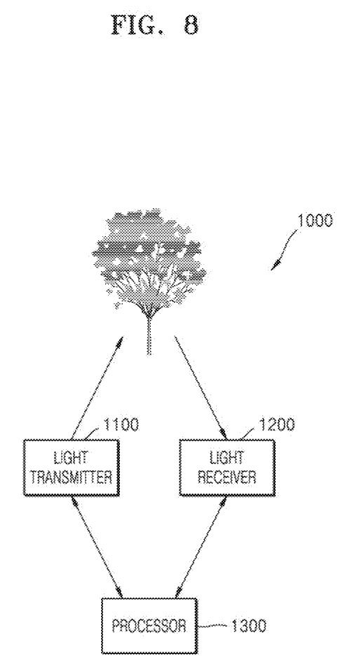

FIG. 8 is a schematic diagram illustrating a Light Detection and Ranging (LiDAR) device 1000 according to one or more embodiments.

As illustrated in FIG. 8, the LiDAR device 1000 may include a light transmitter 1100 that radiates light onto a target object, a light receiver 1200 that receives the light reflected from the target object, and a processor 1300 that performs computations to obtain information about the target object from the light received by the light receiver 1200. The light transmitter 1100 may include a light source that generates the light and a steering unit that steers the light output from the light source toward the target object. The LiDAR device 1000 may include an optical waveguide that provides a path for the light to travel within the light transmitter 1100 or the light receiver 1200. The LiDAR device 1000 may include an optical waveguide that provides an optical connection between the light source and the steering unit. The light transmitter 1100, the light receiver 1200, and the processor 1300 may be implemented as separate devices or as a single device.

The light source may be a tunable light source capable of adjusting the wavelength of emitted light. A plurality of laser beams may be emitted from the light source, and among these plurality of laser beams, laser beams having optical coherence with each other may be incident on the steering unit. The light source may generate and output light in a plurality of different wavelength bands. Additionally, the light source may generate and output pulsed light (such as pulsed laser beams or the like) or continuous light (such as continuous-wave (CW) laser beams or the like).

The light source may include the laser diode 100 of FIG. 1. The light source may include an edge-emitting laser (EEL), a vertical-cavity surface-emitting laser (VCSEL), a distributed feedback laser (DFB laser), a light-emitting diode (LED), a superluminescent diode (SLD), or the like.

The steering unit redirects the light from the light source to illuminate the target object and may include an optical phased array (OPA) element, which enables directional control of the light without mechanical movement. The steering unit may transmit amplified light toward a localized region in the front using a one-dimensional or two-dimensional scanning method. For this purpose, the steering unit may steer light focused on a narrow area sequentially or non-sequentially toward one-dimensional or two-dimensional regions in the front at regular time intervals. For example, the steering unit may be configured to emit laser light from bottom to top or from top to bottom toward one-dimensional regions in the front. Additionally, the steering unit may be configured to emit laser light from left to right or from right to left toward one-dimensional regions in the front.

The light receiver 1200 may receive light reflected by a target object and generate an electrical signal based on the received light. The light receiver 1200 may include an array of light detecting elements. The light receiver 1200 may further include a processing circuit.

The processor 1300 may perform computations to obtain information about the target object from light received from the light receiver 1200. Additionally, the processor 1300 may entirely oversee the processing and control of the LiDAR device 1000. The processor 1300 may obtain and process information about the target object. For example, the processor 1300 may obtain and process two-dimensional or three-dimensional image information. The processor 1300 may control the overall operation of the light transmitter 1100, the light receiver 1200, and the like. For example, the processor 1300 may control an electrical signal applied to the OPA device included in the steering unit. The processor 1300 may also analyze parameters such as a distance between the target object and the LiDAR device 1000, a shape of the target object, and the like through numerical information provided by the light receiver 1200.

A three-dimensional image obtained by the processor 1300 may be transmitted to another unit and utilized. For example, this information may be transmitted to the processor 1300 of an autonomous driving device, such as a vehicle, drone, or the like, in which the LiDAR device 1000 is employed. In addition, such information may also be utilized in smartphones, mobile phones, personal digital assistants (PDAs), laptops, personal computers (PCs), wearable devices, and other mobile or non-mobile computing devices.

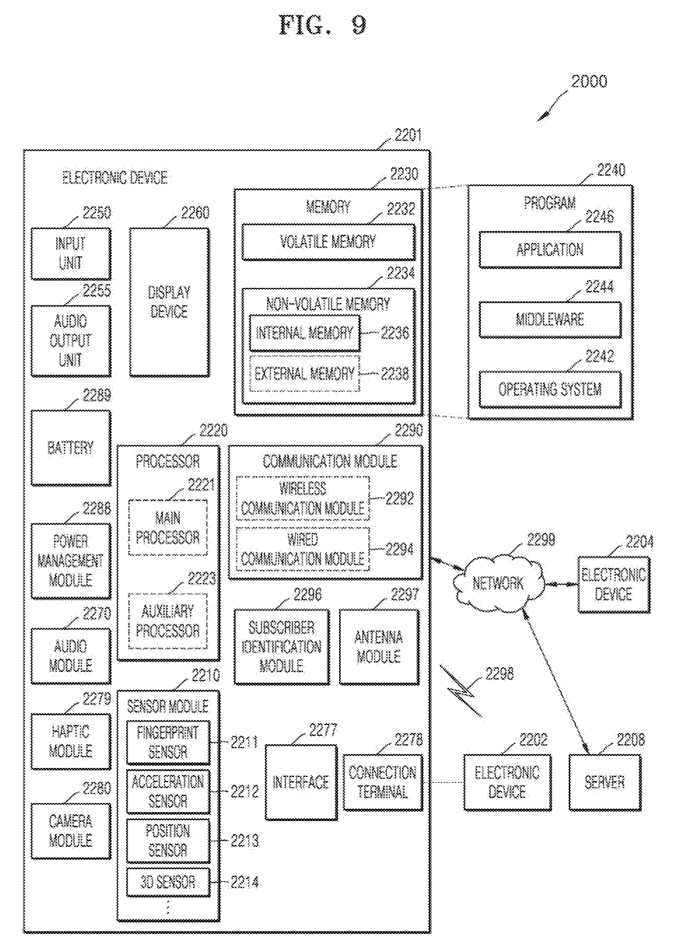

FIG. 9 is a block diagram showing a schematic configuration of an electronic device including a LiDAR device according to one or more embodiments.

Referring to FIG. 9, in a network environment 2000, an electronic device 2201 may communicate with another electronic device 2202 through a first network 2298 such as a short-range wireless communication network, or may communicate with another electronic device 2204 and/or a server 2208 through a second network 2299 such as a long-distance wireless communication network. The electronic device 2201 may communicate with the another electronic device 2204 via the server 2208. The electronic device 2201 may include a processor 2220, a memory 2230, an input unit 2250, an audio output unit 2255, a display device 2260, an audio module 2270, a sensor module 2210, an interface 2277, a haptic module 2279, a camera module 2280, a power management module 2288, a battery 2289, a communication module 2290, a subscriber identification module 2296, and/or an antenna module 2297. In the electronic device 2201, some of these components such as the display device 2260 may be omitted, or other components may be added. Some of these components may be implemented as a single integrated circuit. For example, a fingerprint sensor 2211, an iris sensor, an illuminance sensor, and the like within the sensor module 2210 may be implemented by being embedded into the display device 2260.

The processor 2220 may execute software, such as a program 2240, to control one or more other components, such as hardware or software components, of the electronic device 2201 connected to the processor 2220 and may perform various data processing or computations. As part of data processing or computations, the processor 2220 may load commands and/or data received from other components, such as the sensor module 2210, the communication module 2290, into a volatile memory 2232, process the commands and/or data stored in the volatile memory 2232, and store resulting data in a non-volatile memory 2234. The processor 2220 may include a main processor 2221, such as a central processing unit or an application processor, and an auxiliary processor 2223, such as a graphics processing unit, an image signal processor, a sensor hub processor, and a communication processor, which may operate independently or together with the main processor 2221. The auxiliary processor 2223 uses less power than the main processor 2221 and may perform specialized functions.

The auxiliary processor 2223 may control functions and/or states of some components of the electronic device 2201, such as the display device 2260, the sensor module 2210, the communication module 2290, and the like, either on behalf of the main processor 2221 while the main processor 2221 is in an inactive state (sleep state) or in conjunction with the main processor 2221 while the main processor 2221 is in an active state (application execution state). The auxiliary processor 2223, such as the image signal processor or the communication processor, may also be implemented as part of other functionally related components, such as the camera module 2280, the communication module 2290, and the like.

The memory 2230 may store various data required by the components of the electronic device 2201, such as the processor 2220 or the sensor module 2210. The data may include, for example, input data and/or output data for the software, such as the program 2240, and instructions associated the software. The non-volatile memory 2234 may include internal memory 2236 and external memory 2238. The memory 2230 may include the volatile memory 2232 and/or the non-volatile memory 2234.

The program 2240 may be stored as the software in the memory 2230 and may include an operating system 2242, a middleware 2244, and/or application 2246.

The input unit 2250 may receive commands and/or data to be used in the components of the electronic device 2201, such as the processor 2220, from an external source, such as a user, and the like, of the electronic device 2201. The input unit 2250 may include a microphone, a mouse, a keyboard, and/or a digital pen, such as a stylus pen.

The audio output unit 2255 may output audio signals outside the electronic device 2201. The audio output unit 2255 may include a speaker and/or a receiver, such as an earpiece. The speaker may be used for general purposes, such as playing multimedia or playing recordings, and the receiver may be used for receiving incoming calls. The receiver may be integrated as part of the speaker or implemented as a separate, independent device.

The display device 2260 may visually present information externally from the electronic device 2201. The display device 2260 may include a display unit, a holographic unit, or a projector unit, and corresponding control circuitry for the included unit or units. The display device 2260 may include touch circuitry configured to detect a touch and/or sensor circuitry, such as a pressure sensor or the like, configured to measure intensity of a force generated by a touch.

The audio module 2270 may convert sound into electrical signals or, conversely, convert electrical signals into sound. The audio module 2270 may acquire sound through the input unit 2250 or output sound through the speaker and/or headphones of the audio output unit 2255, and/or another electronic device, such as an electronic device 2202 or the like, that is directly or wirelessly connected to the electronic device 2201.

The sensor module 2210 may detect operating statuses, such as power, temperature, or the like, of the electronic device 2201, or external environmental statuses, such as a user status or the like, and generate an electrical signal and/or data value corresponding to the detected statuses. The sensor module 2210 may include the fingerprint sensor 2211, an acceleration sensor 2212, a position sensor 2213, a 3D sensor 2214, and the like, and may further include, in addition, the iris sensor, a gyro sensor, a pressure sensor, a magnetic sensor, a grip sensor, a proximity sensor, a color sensor, an infrared (IR) sensor, a biometric sensor, a temperature sensor, a humidity sensor, and/or the illuminance sensor.

The 3D sensor 2214 senses a shape, movement, and the like of a subject (target object) by irradiating a predetermined light onto the subject and analyzing the light reflected from the subject. The LiDAR device 1000 described in FIG. 8 may be employed.

The interface 2277 may support one or more designated protocols that may be used for the electronic device 2201 to connect directly or wirelessly with another electronic device, such as the electronic device 2202. The interface 2277 may include a high-definition multimedia interface (HDMI), a universal serial bus (USB) interface, a secure digital (SD) card interface, and/or an audio interface.

A connection terminal 2278 may include a connector that allows the electronic device 2201 to be physically connected to another electronic device, such as the electronic device 2202 or the like. The connection terminal 2278 may include an HDMI connector, a USB connector, an SD card connector, and/or an audio connector, such as a headphone connector or the like.

The haptic module 2279 may convert electrical signals into mechanical stimuli, such as vibration, movement, or the like, or into electrical stimuli that a user can perceive through tactile or kinesthetic sensations. The haptic module 2279 may include a motor, a piezoelectric element, and/or an electrical stimulation device.

The camera module 2280 may capture still images and videos. The camera module 2280 may include a lens assembly including one or more lenses, image sensors, image signal processors, and/or flashes. The lens assembly included in the camera module 2280 may collect light emitted from a subject that is a target of image capture.

The power management module 2288 may manage power supplied to the electronic device 2201. The power management module 2288 may be implemented as part of a power management integrated circuit (PMIC).

The battery 2289 may supply power to the components of the electronic device 2201. The battery 2289 may include a non-rechargeable primary battery, a rechargeable secondary battery, and/or a fuel cell.

The communication module 2290 may support establishment of a direct (wired) communication channel and/or a wireless communication channel between the electronic device 2201 and another electronic device, such as an electronic device 2202, an electronic device 2204, a server 2208, or the like, and performance of communication through an established communication channel. The communication module 2290 may operate independently from the processor 2220, such as the application processor, and may include one or more communication processors that support direct communication and/or wireless communication. The communication module 2290 may include a wireless communication module 2292, such as a cellular communication module, a short-range wireless communication module, a Global Navigation Satellite System (GNSS) communication module, or the like, and/or a wired communication module 2294, such as a local area network (LAN) communication module, a power line communication module, or the like. Any of these communication modules may communicate with other electronic devices via the first network 2298, which is a short-range communication network including Bluetooth, WiFi Direct, Infrared Data Association (IrDA) or the like, or via the second network 2299, which is a long-range communication network including a cellular network, the Internet, or a computer network such as LAN, a wide area network (WAN), or the like. These different types of communication modules may be integrated into a single component, such as a single chip or the like, or implemented as multiple separate components, such as multiple chips. The wireless communication module 2292 may identify and authenticate the electronic device 2201 within the wireless communication network, such as the first network 2298 and/or the second network 2299, using subscriber information, such as an international mobile subscriber identity (IMSI) stored in the subscriber identification module 2296.

The antenna module 2297 may transmit or receive signals and/or power to or from an external source, such as another electronic device. An antenna may include a radiator formed of a conductive pattern on a substrate, such as a printed circuit board (PCB). The antenna module 2297 may include one or a plurality of antennas. When the plurality of antennas are included, an antenna suitable for a communication method used in the communication network, such as the first network 2298 and/or the second network 2299, may be selected from among the plurality of antennas by the communication module 2290. Signals and/or power may be transmitted or received between the communication module 2290 and another electronic device through the selected antenna. In addition to the antennas, other components, such as a radio frequency integrated circuit (RFIC) or the like, may be included as part of the antenna module 2297.

Some of the components may be connected to each other and exchange signals, such as commands, data, or the like, through communication methods between peripheral devices, such as a bus, General Purpose Input and Output (GPIO), Serial Peripheral Interface (SPI), Mobile Industry Processor Interface (MIPI), or the like.

Commands or data may be transmitted or received between the electronic device 2201 and the another electronic device 2204 through the server 2108 connected to the second network 2299. The other electronic devices 2202 and 2204 may be the same type as, or a different type of device from, the electronic device 2201. All or part of the operations executed on the electronic device 2201 may be executed on one or more of the other electronic devices 2202, 2204, or 2208. For example, when the electronic device 2201 needs to perform a function or service, instead of executing the function or service on its own, the electronic device 2201 may request one or more other electronic devices to perform all or part of the function or service. One or more other electronic devices that receive a request may execute additional functions or services related to the request and transmit results of the execution to the electronic device 2201. For this purpose, cloud computing, distributed computing, and/or client-server computing technologies may be utilized.

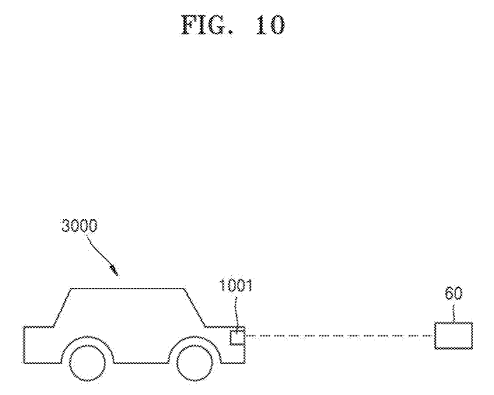

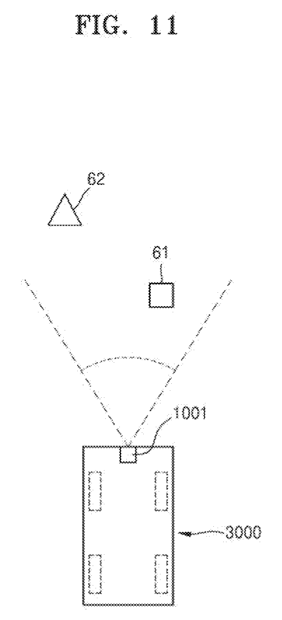

FIGS. 10 and 11 are conceptual diagrams, where FIG. 10 is a side view and FIG. 11 is a plan view, illustrating the application of the LiDAR device according to the embodiment in a vehicle.

Referring to FIG. 10, a LiDAR device 1001 may be applied to a vehicle 3000, and information on a subject 60 may be obtained using the LiDAR device 1001. The LiDAR device 1001 may employ the LiDAR device 1000 described in FIG. 8. The LiDAR device 1001 may use the time-of-flight (TOF) method to obtain information about the subject 60. The vehicle 3000 may be a car having autonomous driving functions. Using the LiDAR device 1001, an object or person, i.e., the subject 60, in the direction in which the vehicle 3000 is moving may be detected, and a distance to the subject 60 may be measured using information such as a time difference between a transmission signal and a detection signal. In addition, as illustrated in FIG. 11, information on a nearby subject 61 and a distant subject 62 within a target field may be obtained.

FIGS. 10 and 11 illustrate that the LiDAR device may be applied to automobiles but are not limited thereto. The LiDAR device may be applied to flying objects such as drones, mobile devices, small walking devices (e.g., bicycles, motorcycles, baby strollers, boards, etc.), robots, human/animal assistance devices (e.g., canes, helmets, accessories, clothing, watches, bags, etc.), Internet of Things (IoT) devices/systems, security devices/systems, and the like.

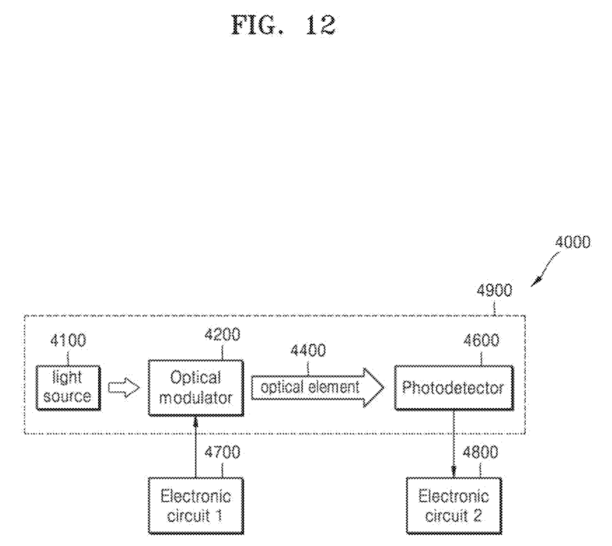

FIG. 12 is a block diagram conceptually showing an exemplary configuration of an optical integrated circuit 4000 according to one or more embodiments.

The optical integrated circuit 4000 may include a light source (e.g., a laser) 4100, an optical element 4400 that transmits light from the light source 4100, and a photodetector 4600 that converts light transmitted from the optical element 4400 into an electrical signal. The optical element 4400 may include a splitter, a ring resonator, a grating coupler, etc. in addition to a single waveguide. The light source 4100 may include the laser diode 100 described in FIG. 1.

Such a structure may be part of a circuit forming, for example, an optical transceiver. The optical integrated circuit 4000 may further include the light source 4100, an optical modulator 4200 disposed on the optical element 4400, an electronic circuit 4700 that applies modulation signals to the optical modulator 4200, and an electronic circuit 4800 through which electrical signals converted by the photodetector 4600 is transmitted.

The light source 4100, the optical modulator 4200, the optical element 4400, and the photodetector 4600 may be disposed on the same substrate 4900. The substrate 4900 may include a silicon substrate, and the photodetector 4600 may also include a photodiode utilizing a silicon semiconductor.

According to the present embodiment, the laser diode and the optical integrated circuit including the same are provided, wherein the gain may be modulated without affecting the active layer by providing the plurality of pattern layers on the semiconductor layer, and the mode hopping characteristic is improved.

According to the laser diode of the present embodiment and the optical integrated circuit including the same, the laser diode capable of preventing the mode hopping and the optical integrated circuit including the same may be provided. Although the laser diode and the optical integrated circuit including the same have been described with reference to the embodiments shown in the drawings, these are merely exemplary, and it will be understood by those skilled in the art that various modifications and equivalent other embodiments are possible therefrom. Therefore, the disclosed embodiments should be considered in an illustrative rather than a restrictive sense. The scope of the rights is indicated in the claims, not in the foregoing description, and all differences within the equivalent scope should be interpreted as being included in the scope of the rights.

What is claimed is:

1. A laser diode comprising:
a substrate;
a first semiconductor layer, an active layer, and a second semiconductor layer, which are sequentially stacked on the substrate in a vertical direction of the laser diode; and
a plurality of pattern layers spaced apart from each other in a horizontal direction of the laser diode, on the second semiconductor layer,
wherein widths of the plurality of pattern layers are different from each other in the horizontal direction.

2. The laser diode of claim 1, wherein the plurality of pattern layers are spaced apart from each other at non-periodic intervals.

3. The laser diode of claim 1, wherein the widths of the plurality of pattern layers gradually increase along the horizontal direction.

4. The laser diode of claim 1,
wherein the plurality of pattern layers are spaced apart from each other at non-periodic intervals that range from 10 nm to 100 nm.

5. The laser diode of claim 1, wherein the widths of the plurality of pattern layers range from 150 nm to 1,000 nm.

6. The laser diode of claim 1, wherein the plurality of pattern layers comprises silicon oxide.

7. The laser diode of claim 1, wherein a portion of an area of the second semiconductor layer, in which the plurality of pattern layers are not provided, is doped.

8. The laser diode of claim 1, further comprising a first contact provided on the plurality of pattern layers.

9. The laser diode of claim 1, further comprising a second contact provided on the substrate.

10. The laser diode of claim 1, wherein the first semiconductor layer is an n-type semiconductor layer and the second semiconductor layer is a p-type semiconductor layer.

11. The laser diode of claim 1, further comprising a distributed feedback laser.

12. An optical integrated circuit comprising:
a light source;
an optical element configured to transmit light from the light source; and
a photodetector configured to convert the light received through the optical element into an electrical signal,
wherein the light source comprises:
a substrate;
a first semiconductor layer, an active layer, and a second semiconductor layer, which are sequentially stacked on the substrate in a vertical direction of the light source; and
a plurality of pattern layers spaced apart from each other on the second semiconductor layer in a horizontal direction of the light source, wherein the plurality of pattern layers have different widths from each other in the horizontal direction.

13. The optical integrated circuit of claim 12, further comprising an optical modulator disposed on the optical element.

14. The optical integrated circuit of claim 13, further comprising an electronic circuit configured to apply modulation signals to the optical modulator.

15. The optical integrated circuit of claim 12, wherein the plurality of pattern layers are spaced apart from each other at non-periodic intervals.

16. The optical integrated circuit of claim 12, wherein a portion of an area of the second semiconductor layer, in which the plurality of pattern layers are not provided, is doped.

17. A light detection and ranging (LiDAR) device comprising:
a light transmitter configured to radiate light onto a target object;
a light receiver configured to receive the light reflected from the target object;
a processor configured to obtain position information about the target object based on the light received from the light receiver; and
an optical element configured to provide a path for the light to travel within the light transmitter or the light receiver,
wherein the light transmitter comprises a light source, and
the light source comprises:
a substrate;
a first semiconductor layer, an active layer, and a second semiconductor layer, which are sequentially stacked on the substrate in a vertical direction of the light source; and
a plurality of pattern layers spaced apart from each other in a horizontal direction of the light source on the second semiconductor layer, wherein the plurality of pattern layers have different widths from each other in the horizontal direction.

18. The LiDAR device of claim 17, wherein the light transmitter is further configured to steer the light output from the light source toward the target object.

19. The LiDAR device of claim 17, wherein the plurality of pattern layers are spaced apart from each other at non-periodic intervals.

20. The LiDAR device of claim 17, wherein a portion of an area of the second semiconductor layer, in which the plurality of pattern layers are not provided, is doped .
